(19) United States
(12) Patent Application Publication
(10) Pub. No.: US 2013/0068292 A1
(43) Pub. Date: Mar. 21, 2013

(54) ALUMINUM NANOSTRUCTURE ARRAY

(71) Applicants: Zhiyong Fan, Kowloon (CN); Rui Yu, Kowloon (CN)

(72) Inventors: Zhiyong Fan, Kowloon (CN); Rui Yu, Kowloon (CN)

(73) Assignee: THE HONG KONG UNIVERSITY OF SCIENCE AND TECHNOLOGY, Kowloon (CN)

(21) Appl. No.: 13/608,140

(22) Filed: Sep. 10, 2012

Related U.S. Application Data
(60) Provisional application No. 61/573,153, filed on Sep. 16, 2011.

(51) Int. Cl. H01L 31/18; H01L 31/0236; C25D 11/24

(52) U.S. Cl. 136/256; 216/11; 438/71; 257/E31.13

(57) ABSTRACT

Described herein is a method for obtaining a three-dimensional nanostructure array on an aluminum substrate. The method includes anodizing the aluminum substrate; forming an oxide layer on the aluminum substrate; texturizing the aluminum substrate; etching the oxide layer from the aluminum substrate to expose the texturized aluminum substrate; and forming a three-dimensional aluminum nanostructure array on the aluminum substrate. The three-dimensional nanostructure array, coated with a light absorber, is utilized in a thin film solar cell or photovoltaic cell.

### CROSS REFERENCE TO RELATED APPLICATION

This application claims priority to U.S. provisional application Ser. No. 61/573,153, entitled: “SELF-ORDERED THREE-DIMENSIONAL ALUMINUM NANOSPIKE ARRAYS FOR EFFICIENT LIGHT ABSORPTION AND PHOTOVOLTAIC APPLICATION,” and filed on Sep. 16, 2011.

### TECHNICAL FIELD

This disclosure generally relates to generation of a three-dimensional aluminum nanostructure array and to applications of the three-dimensional aluminum nanostructure array.

### BACKGROUND

Nanostructures can be used in antireflection coatings for solar cell applications. Three dimensional nanostructures, such as nanotubes, nanorods, nanopillars, nanocones, nanodomes, nanowires, and the like are attractive for antireflection coatings because three-dimensional nanostructures have large surface areas. The large surface area of three-dimensional nanostructures, compared to the surface structure of two dimensional textured substrates, facilitates broadband and more efficient light absorption.

Various top-down and bottom-up methods have been developed to build three-dimensional nanostructures, such as vapor-liquid solid growth, photolithography, nanotransfer printing, and micromolding in capillaries. Although the resulting three-dimensional nanostructures have proven to be effective in the facilitation of broadband and efficient light trapping, these top-down and bottom-up methods are expensive and complicated with poor controllability and scalability. The cost, complexity, controllability, and scalability of the top-down and bottom-up methods limit the applicability of three-dimensional nanostructures fabricated according to these top-down and bottom-up methods for practical applications as antireflective coatings for solar cells.

The above-described background is merely intended to provide an overview of contextual information regarding the formation of three-dimensional nanostructures and the use of the three-dimensional nanostructures in antireflection coatings, and is not intended to be exhaustive. Additional context may become apparent upon review of one or more of the various non-limiting embodiments of the following detailed description.

### SUMMARY

The following presents a simplified summary of the specification in order to provide a basic understanding of some aspects of the specification. This summary is not an extensive overview of the specification. It is intended to neither identify key or critical elements of the specification nor delineate any scope of particular embodiments of the specification, or any scope of the claims. Its sole purpose is to present some concepts of the specification in a simplified form as a prelude to the more detailed description that is presented later.

In accordance with one or more embodiments and corresponding disclosure, various non-limiting aspects are described in connection with a three-dimensional aluminum nanostructure array. According to an embodiment, a method for forming the three-dimensional aluminum nanostructure array is described. The method includes anodizing an aluminum substrate; forming an oxide layer on the aluminum substrate; texturizing the aluminum substrate; etching the oxide layer from the aluminum substrate to expose the texturized aluminum substrate; and forming a three-dimensional aluminum nanostructure array on the aluminum substrate.

In a further embodiment, a three-dimensional solar cell is described. The solar cell includes a three-dimensional aluminum nanostructure array formed on a thin film aluminum substrate. The solar cell also includes a light absorber that coats the three-dimensional aluminum nanostructure array.

In another embodiment, a photovoltaic cell is described. The photovoltaic cell includes a three-dimensional aluminum nanospike array formed on an aluminum substrate. The photovoltaic cell also includes a light absorber that coats the three-dimensional aluminum nanostructure array. The three-dimensional aluminum nanospike array coated with the light absorber exhibits a reflectance of about 5 percent or less.

The following description and the drawings set forth certain illustrative aspects of the specification. These aspects are indicative, however, of but a few of the various ways in which the various embodiments of the specification may be employed. Other aspects of the specification will become apparent from the following detailed description of the specification when considered in conjunction with the drawings.

### BRIEF DESCRIPTION OF THE DRAWINGS

Numerous aspects and embodiments are set forth in the following detailed description, taken in conjunction with the accompanying drawings, in which like reference characters refer to like parts throughout, and in which:

FIG. 1 is an example non-limiting process flow diagram of a method for forming a three-dimensional aluminum nanostructure array, according to an embodiment;

FIG. 2 is an example non-limiting schematic diagram of the method for forming a three-dimensional aluminum nanospike array, according to an embodiment;

FIG. 3 is an example non-limiting illustration of a scanning electron microscope image of a three-dimensional aluminum surface structure with different anodization voltages, according to an embodiment;

FIG. 4 is an example non-limiting process flow diagram of a method for forming an antireflection coating, according to an embodiment;

FIG. 5 is an example non-limiting system block diagram of an example solar cell, according to an embodiment;

FIG. 6 is an example non-limiting system block diagram of an example photovoltaic cell, according to an embodiment;

FIG. 7 is an example non-limiting illustration of a scanning electron microscope image of a three-dimensional aluminum nanospike array deposited with amorphous silicon, according to an embodiment;

FIG. 8 is an example non-limiting graph illustrating reflectance spectra of aluminum nanospike arrays deposited with amorphous silicon, according to an embodiment.

FIG. 9 is an example non-limiting illustration of a scanning electron microscope image of a three-dimensional aluminum nanospike array deposited with cadmium telluride, according to an embodiment; and

FIG. 10 is an example non-limiting graph showing reflectance spectra of aluminum nanospike arrays deposited with cadmium telluride, according to an embodiment.

### DETAILED DESCRIPTION

Various aspects or features of this disclosure are described with reference to the drawings, wherein like reference numerals are used to refer to like elements throughout. In this specification, numerous specific details are set forth in order to provide a thorough understanding of this disclosure. It should be understood, however, that the certain aspects of disclosure may be practiced without these specific details, or with other methods, components, molecules, etc. In other instances, well-known structures and devices are shown in block diagram form to facilitate description and illustration of the various embodiments.

In accordance with one or more embodiments described in this disclosure, described herein is a self-ordered three-dimensional nanostructure array that is formed on an aluminum surface according to a low-cost and scalable method. Coated with a light absorbing thin film material, the three-dimensional nanostructure array exhibit more efficient light absorption capabilities when compared to a planar thin film with the same thickness.

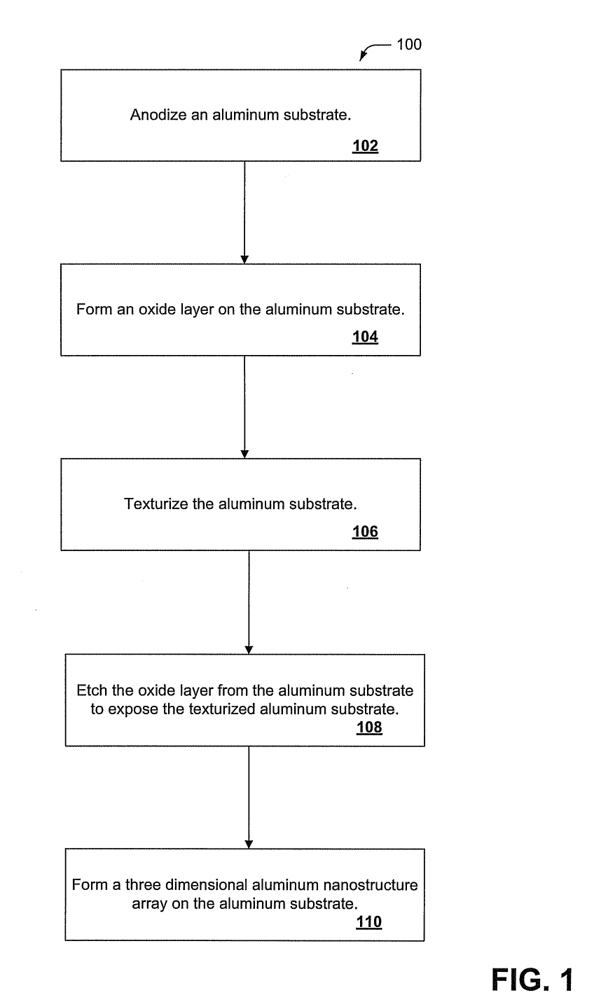

Referring now to the drawings, with reference initially to FIG. 1, is an example non-limiting process flow diagram of a method 100 for forming a three-dimensional aluminum nanostructure array, according to an embodiment. Method 100 is a low cost and scalable process to obtain self-ordered three-dimensional nanostructure arrays on an aluminum surface. The three-dimensional nanostructure formed by method 100 acts as a template that can be coated with a thin layer of an anti-reflection material to facilitate light trapping applications.

In the past, technologies to produce three-dimensional nanostructures for light trapping applications have been predominantly based on lithography, vacuum-based etching, and vapor phase growth. Although the resulting three-dimensional nanostructures proven effective for light trapping, high cost and poor scalability of the production methods have limited the practical applications for nanostructures formed according to lithography, vacuum-based etching, and vapor phase growth.

Method 100 utilizes self-organized anodization in an electrolyte solution (or a solution based process) to facilitate formation of the nanostructures. The solution based process, performed with water and common, inexpensive chemicals, has a comparatively low cost and good scalability compared to lithography, vacuum-based etching, and vapor phase growth. Moreover, method 100 can produce substantially uniform three-dimensional nanostructure arrays with a high density.

At element 102, an aluminum substrate is anodized. The aluminum substrate generally refers to any substrate with at least one surface being aluminum. In an embodiment, the aluminum substrate has a thin layer or thin film of aluminum surface. An example of a thin layer aluminum surface is aluminum foil. Aluminum foil is light weight, flexible, and low cost.

Anodization refers to any process in which electric current is passed through an electrolytic solution containing the aluminum substrate with the aluminum substrate acting as the anode.

The anodization facilitates the growth of an anodized aluminum layer on the surface of the aluminum substrate. When the current is passed through the electrolytic solution, the current releases hydrogen at the cathode and oxygen at the surface of the aluminum substrate anode. At element 104, an oxide layer (also referred to as aluminum oxide, Al₂O₃, or porous alumina membrane) is formed on the aluminum substrate.

The anodization is a high voltage anodization process. The voltage of the anodization can be varied to facilitate growth of oxide layers of different thicknesses (which can correlate to the size of the three-dimensional nano structures, such as height and/or pitch). In an embodiment, the voltage is from about 100 Volts to about 1000 Volts. In a further embodiment, the voltage is from about 150 Volts to about 900 Volts. In another embodiment, the voltage is from about 200 Volts to about 600 Volts.

The anodization can be performed in an electrolytic solution that is acidic (pH less than 7.0). The acidity of the electrolyte solution facilitates dissolving the oxide layer. The acidity is balanced with the oxidation rate to form the oxide coating with nanopores. The nanopores allow the electrolyte solution and the current to reach the aluminum substrate and facilitate the growth of nanostructures. According to an embodiment, the nanopores can have a diameter of from about 10 nm-about 150 nm. The concentration of the electrolyte solution can be varied to facilitate formation of different sized pores that can facilitate the growth of the nano structures.

Conditions of the anodization, such as electrolyte concentration, acidity, solution temperature, and the like can be controlled to facilitate the formation of a consistent oxide layer. The electrolytic solution, according to an embodiment, is a solution that contains citric acid and ethylene glycol. The citric acid and ethylene glycol can be present in the electrolytic solution in a ratio of about 1:1 to about 2:1. The citric acid can have a concentration from about 1 weight percent to about 4 weight percent. The electrolyte can, according to another embodiment, utilize phosphoric acid.

The anodization changes the microscopic texture of the aluminum surface and changes the crystal structure of the aluminum near the surface. At element 106, the aluminum substrate is texturized. The texturization of the aluminum substrate facilitates the formation of nanostructures on the surface of the aluminum substrate. In an embodiment, the texturization of the aluminum surface is facilitated by the pores of the oxide layer, the acidity of the electrolyte, and/or the high voltage (and the associated current).

At element 108, the oxide layer is etched from the aluminum substrate to expose the texturized aluminum substrate. The etching can be performed utilizing an acid. In an embodiment, the acid used for etching includes phosphoric or chromic acid. In another embodiment, the acid used for etching includes both phosphoric acid and chromic acid. The phosphoric acid has a concentration from about 0.1 weight percent to about 0.2 weight percent and the chromic acid has a concentration from about 4 weight percent to about 6 weight percent, in an embodiment. In a further embodiment, the phosphoric acid has a concentration of about 0.18 weight percent and the chromic acid has a concentration of about 6 weight percent.

At element 110, a three-dimensional aluminum nanostructure array is formed on the aluminum substrate. When used herein, the term nanostructure refers generally to any self-ordered, three-dimensional array formed during texturization of the aluminum substrate. Examples of a nanostructure include: a nanospike array, a concave array, a nanopillar array, or the like. Further examples of a nanostructure include: a nanotube, a nanorod, a nanocone, a nanodome, a nanowire, and arrays thereof.

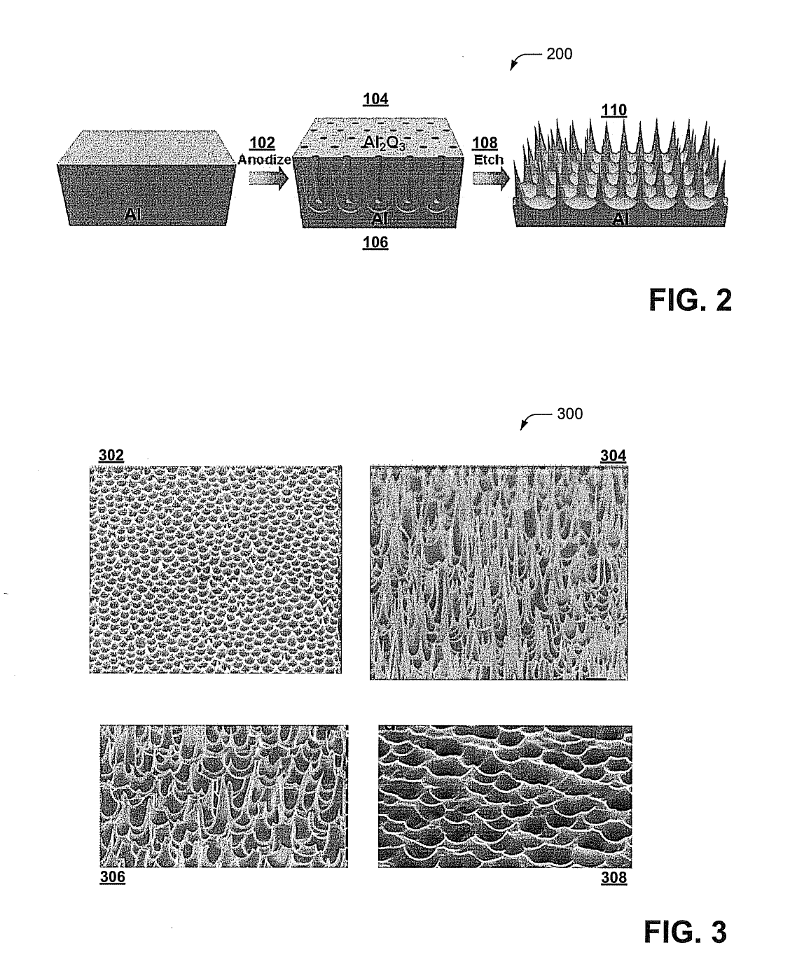

One example of a nanostructure that can be formed according to method 100 is a nanospike array. Referring now to FIG. 2, illustrated is an example non-limiting schematic diagram 200 of the method 100 for forming the three-dimensional aluminum nanospike array. For example, the nanospike array can be formed on aluminum foil. In FIG. 2, reference numbers 102, 104, 106, 108 and 110 correspond to the process steps of method 100.

The high voltage anodization of the aluminum substrate 102 with the specific formulation of the electrolyte described above facilitates the formation of nanospike arrays on the surface of the aluminum substrate 110. With the anodization 102 and etching 108 scheme shown in FIG. 2, large scale, low cost, high throughput, controllable formation of self-ordered three-dimensional aluminum nanospike surface structures can be achieved.

The self-ordered three-dimensional aluminum nanospike surface structures which can be used for general anti-reflection applications. The anti-reflection applications can, for example, improve solar cell efficiency. Specifically, the anodization 102 promotes growth of a porous oxide membrane 104 on the aluminum substrate while texturizing 106 the aluminum substrate. The etching process 108 removes the porous alumina membrane, exposing the texturized aluminum substrate. Different from previous methods, method 100, as illustrated in FIG. 2, yields true three-dimensional nanospike arrays on the aluminum substrate.

Due to the self-ordering formation of the nanospikes on the aluminum surface, the exact pitch and spike height of the nanospikes can be controlled. For example, different voltages can be applied to achieve different pitches or spike heights. In an example, the three-dimensional aluminum nanospike array can have a spike height of about 5 μm or less and a spike pitch of about 1.3 μm or less.

Examples of different spike heights and different spike pitches under different voltage conditions are shown in FIG. 3. Utilizing this anodization 102 and etching 108 process as shown in FIGS. 1 and 2, different aluminum nanostructures can be realized. For example, these aluminum nanostructures can be utilized in connection with low-cost and high performance photovoltaics. To achieve the nanostructures of FIG. 3, aluminums chips were anodized at different voltages: 200 Volts, 400 Volts, 500 V, and 600 Volts to form an oxide layer on the surface of the aluminum substrate, followed by the subsequent etching of the oxide layer to expose the three-dimensional nanostructure.

FIG. 3 illustrates that for different anodization voltages, different nanostructures are formed. At 302, a scanning electron microscope image of a three-dimensional aluminum surface structure with an anodization voltage of 200 Volts is shown. At 304, a scanning electron microscope image of a three-dimensional aluminum surface structure with an anodization voltage of 400 Volts is shown. At 306, a scanning electron microscope image of a three-dimensional aluminum surface structure with an anodization voltage of 500 Volts is shown. At 308, a scanning electron microscope image of a three-dimensional aluminum surface structure with an anodization voltage of 600 Volts is shown.

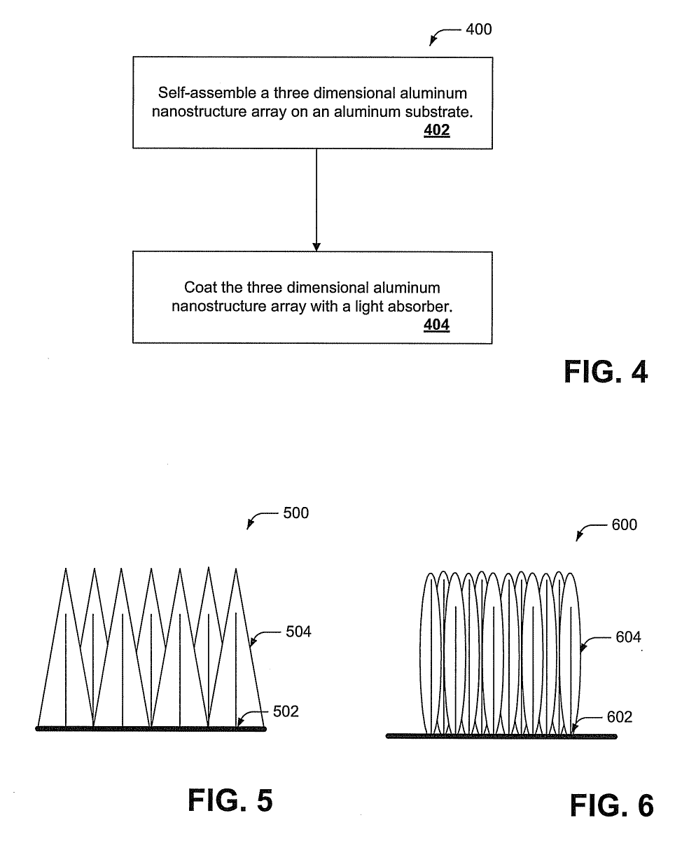

Referring now to FIG. 4, illustrated is an example non-limiting process flow diagram of a method 400 for forming an antireflection coating, according to an embodiment.

At element 402, a three-dimensional aluminum nanostructure array is self-assembled on an aluminum substrate according to the process illustrated in FIGS. 1 and 2. The three-dimensional aluminum nanospike array can be utilized as a template to facilitate a light absorber achieving a three-dimensional structure.

At element 404, the three-dimensional aluminum nanostructure array is coated with a light absorber. The coating can be a thin layer of one or more light absorbers (also referred to as photovoltaic materials). The thin layer can have a thickness from about 1 nm to about 1000 nm. According to an embodiment, the thin layer has a thickness of about 40 nm-about 400 nm. In another embodiment, the thin layer has a thickness on the order of 100 nm. Examples of light absorbers include cadmium telluride and amorphous silicon. Amorphous silicon generally refers to any non-crystalline form of silicon.

After coating the three-dimensional aluminum nanostructure with the thin layer or thin film of light absorbing material, the three-dimensional aluminum nanostructure array exhibits an efficient light absorption capability compared to planar thin film solar cells. Thin film solar cells developed with the light absorber coated three-dimensional aluminum nanostructure array provide a cost effective solution for many applications requiring solar energy, such as: portable electronics, solar panels, solar curtains, and the like.

Example applications of the light absorber coated three-dimensional aluminum nanostructure include a three-dimensional solar cell (FIG. 5 illustrates a schematic cross sectional diagram of an example solar cell the substrate 502 with the three-dimensional nanostructure coated with an anti-reflective coating 504) and a three-dimensional photovoltaic cell (FIG. 6 illustrates a schematic cross sectional diagram of an example photovoltaic cell with the aluminum substrate 602 with the three-dimensional nanostructure coated with an anti-reflective coating 604). It will be understood that other applications can be similarly realized with the light absorber coated three-dimensional aluminum nanostructure.

The three-dimensional solar cell includes a three-dimensional aluminum nanostructure array formed on a thin film aluminum substrate (e.g., formed according to the process illustrated in FIG. 1 or 2); and a light absorber that coats the three-dimensional aluminum nanostructure array. The three-dimensional photovoltaic cell also includes a three-dimensional aluminum nanospike array formed on an aluminum substrate (according to the process illustrated in FIGS. 1 and 2); and a light absorber that coats the three-dimensional aluminum nanostructure array. In each case, the three-dimensional aluminum nanospike array coated with the light absorber exhibits a reflectance of about 5 percent or less. The reflectance of about 5 percent or less is low compared to the reflectance exhibited by the light absorber coated on a planar aluminum substrate.

Light absorbers amorphous silicon and cadmium telluride were coated as thin layers (about 100 nm) on template three-dimensional nanospike arrays formed according to the process described in FIGS. 1 and 2. The three-dimensional nanospike arrays were formed under anodization voltages of 200 Volts, 400 Volts, 500 Volts and 600 Volts anodization voltages, realizing nanostructures as shown in FIG. 3. Optical properties of the coated templates show that the three-dimensional nanospike arrays of aluminum-amorphous silicon and aluminum-cadmium telluride have much improved optical absorption, as compared to planar thin films of these materials with the same thickness. These results indicate that these unique three-dimensional nanostructures have promising potential for fabricating cost-effective thin film solar cells.

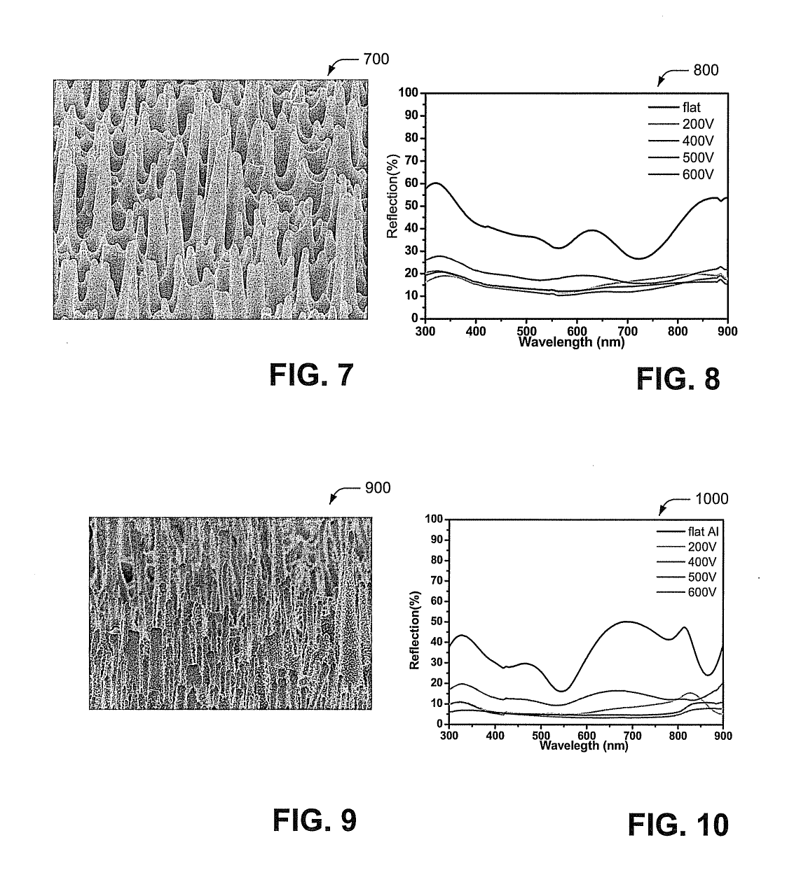

Optical measurements show a strong light absorption capability of the three-dimensional aluminum nanospike arrays coated with both amorphous silicon and cadmium telluride, indicating their promising potential for a new type of three-dimensional thin film solar cells. Notably, although there have been previous attempts to fabricate amorphous silicon solar cells on a textured aluminum surface after anodization, the previous textures were not three-dimensional nanostructures. Thus, the optical absorption enhancement due to the two-dimensional anodized aluminum was quite limited. However, as illustrated in FIGS. 7-10, the aluminum nanospikes formed according to the process illustrated in FIGS. 1 and 2 are true three-dimensional structures with controlled spike height and pitch.

FIGS. 7 and 8 relate to aluminum nanospike arrays deposited with amorphous silicon, according to an embodiment. FIGS. 9 and 10 relate to aluminum nanospike arrays deposited with cadmium telluride, according to an embodiment.

FIG. 7 is a scanning electron microscope image 700 of an aluminum nanospike array deposited with amorphous silicon. The scanning electron microscope image 700 shows that a thin layer of amorphous silicon (100 nm) was deposited on the aluminum nanospike array with vary uniform coverage. The uniform coverage is advantageous for subsequent solar cell fabrication.

FIG. 8 is a graph 800 illustrating reflectance spectra of aluminum nanospike arrays (formed according to the process described in FIGS. 1 and 2) deposited with a thin layer (100 nm) of amorphous silicon. The three-dimensional nanospike arrays were formed under anodization voltages of 200 Volts, 400 Volts, 500 Volts and 600 Volts anodization voltages, realizing nanostructures as shown in FIG. 3. A flat aluminum substrate coated with a thin layer (100 nm) of amorphous silicon was used as a control. The three-dimensional nanospike arrays were formed under anodization voltages of 200 Volts, 400 Volts, 500 Volts and 600 Volts anodization voltages all show a reflectance less than the planar aluminum substrate in the 400 nm-800 nm range.

FIG. 9 is a scanning electron microscope image 900 of an aluminum nanospike array deposited with cadmium telluride. The three-dimensional nanospike arrays were formed under anodization voltages of 200 Volts, 400 Volts, 500 Volts and 600 Volts anodization voltages, realizing nanostructures as shown in FIG. 3. The scanning electron microscope image 900 shows that a thin layer of cadmium telluride (100 nm) was deposited on the aluminum nanospike array with vary uniform coverage. The uniform coverage is advantageous for subsequent solar cell fabrication.

FIG. 10 is an example non-limiting graph 1000 showing reflectance spectra of aluminum nanospike arrays deposited with cadmium telluride, according to an embodiment. A flat aluminum substrate coated with a thin layer (100 nm) of amorphous silicon was used as a control. The three-dimensional nanospike arrays were formed under anodization voltages of 200 Volts, 400 Volts, 500 Volts and 600 Volts anodization voltages all show a reflectance less than the planar aluminum substrate in the 400 nm-800 nm range.

What has been described above includes examples of the embodiments of the subject disclosure. It is, of course, not possible to describe every conceivable combination of components or methods for purposes of describing the claimed subject matter, but it is to be appreciated that many further combinations and permutations of the various embodiments are possible. Accordingly, the claimed subject matter is intended to embrace all such alterations, modifications, and variations that fall within the spirit and scope of the appended claims. While specific embodiments and examples are described in this disclosure for illustrative purposes, various modifications are possible that are considered within the scope of such embodiments and examples, as those skilled in the relevant art can recognize.

In addition, the words “example” or “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

In addition, while an aspect may have been disclosed with respect to only one of several embodiments, such feature may be combined with one or more other features of the other embodiments as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements. \Numerical data, such as temperatures, concentrations, times, ratios, and the like, are presented herein in a range format. The range format is used merely for convenience and brevity. The range format is meant to be interpreted flexibly to include not only the numerical values explicitly recited as the limits of the range, but also to include all the individual numerical values or sub-ranges encompassed within the range as if each numerical value and sub-range is explicitly recited. When reported herein, any numerical values are meant to implicitly include the term “about.” Values resulting from experimental error that can occur when taking measurements are meant to be included in the numerical values.

What is claimed is:

1. A method, comprising:
anodizing an aluminum substrate;
forming an oxide layer on the aluminum substrate;
texturizing the aluminum substrate;
etching the oxide layer from the aluminum substrate to expose the texturized aluminum substrate; and
forming a three-dimensional aluminum nanostructure array on the aluminum substrate.

2. The method of claim 1, further comprising coating the three-dimensional aluminum nanostructure array with a light absorber.

3. The method of claim 2, wherein the coating further comprises coating the three-dimensional aluminum nanostructure array with at least one of cadmium telluride or amorphous silicon.

4. The method of claim 2, wherein the coating further comprises coating the three-dimensional aluminum nanospike array with a thin layer of the light absorber.

5. The method of claim 1, wherein the anodizing further comprises anodizing the aluminum substrate at a voltage from about 100 Volts to about 1000 Volts.

6. The method of claim 1, wherein the anodizing further comprises anodizing the aluminum substrate using an electrolytic solution comprising citric acid and ethylene glycol.

7. The method of claim 6, wherein the citric acid concentration is from about 1 weight percent to about 4 weight percent.

8. The method of claim 1, wherein the etching further comprises etching the oxide layer from the aluminum substrate in a mixture of phosphoric acid and chromic acid.

9. The method of claim 8, wherein the phosphoric acid has a concentration of about 0.18 weight percent and the chromic acid has a concentration of about 6 weight percent.

10. The method of claim 1, wherein the forming further comprises forming a nanospike array, a concave array, or a nanopillar array.

11. The method of claim 1, wherein the forming further comprises forming a self-ordered three-dimensional aluminum nanospike array with a spike height of about 5 μm or less and a spike pitch of about 1.3 μm or less.

12. A three-dimensional solar cell, comprising:
a three-dimensional aluminum nanostructure array formed on a thin film aluminum substrate; and
a light absorber that coats the three-dimensional aluminum nanostructure array.

13. The three-dimensional solar cell of claim 12, wherein the light absorber is a thin film coating the three-dimensional aluminum nanostructure array.

14. The three-dimensional solar cell of claim 12, wherein the light absorber comprises at least one of cadmium telluride or amorphous silicon.

15. The three-dimensional solar cell of claim 12, wherein the three-dimensional aluminum nanostructure array is a nanospike array, a concave array, or a nanopillar array.

16. The three-dimensional solar cell of claim 12, wherein the three-dimensional aluminum nanostructure array is formed on the thin film aluminum substrate by an anodization and etching process.

17. A photovoltaic cell, comprising:
a three-dimensional aluminum nanospike array formed on an aluminum substrate; and
a light absorber that coats the three-dimensional aluminum nanostructure array,
wherein the three-dimensional aluminum nanospike array coated with the light absorber exhibits a reflectance of about 5 percent or less.

18. The photovoltaic cell of claim 17, wherein the aluminum substrate is a thin film or foil aluminum substrate.

19. The photovoltaic cell of claim 17, wherein the light absorber is a thin film light absorber.

20. The photovoltaic cell of claim 17, wherein the light absorber comprises at least one of cadmium telluride or amorphous silicon.
